(19) United States
(12) Patent Application Publication
(10) Pub. No.: US 2025/0370016 A1
(43) Pub. Date: Dec. 4, 2025

(54) ISOLATION RESISTANCE MONITORING SYSTEM

(71) Applicant: GM Global Technology Operations LLC, Detroit, MI (US)

(72) Inventors: Akshay Sarin, Troy, MI (US); David S. Thompson, Warren, MI (US); Rebecca Darr, Milford, MI (US); Manuel Ramos, Windsor (CA)

(73) Assignee: GM Global Technology Operations LLC, Detroit, MI (US)

(21) Appl. No.: 18/680,494

(22) Filed: May 31, 2024

(51) Int. Cl. G01R 27/02; G01R 31/00

(52) U.S. Cl. CPC G01R 27/025; G01R 31/007

(57) ABSTRACT

An isolation resistance monitoring system for a high voltage direct current (DC) system includes a plurality of high voltage systems including a first high voltage link and a second high voltage link, a plurality of isolation monitors operably coupled with each of the first high voltage link and the second high voltage link to detect isolation resistance data, and a controller including data processing hardware configured to execute an isolation monitoring algorithm. The data processing hardware is also configured to execute an isolation function based on the isolation resistance. The isolation monitoring algorithm is configured to determine an isolation resistance level of each of the first high voltage link and the second high voltage link based on the isolation resistance data.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to an isolation resistance monitoring system.

Vehicle systems typically monitor a resistance level of high voltage systems. The vehicle systems are designed to have a certain level of isolation and to monitor what the isolation looks like. The vehicle systems are equipped with monitoring devices to track the resistance levels and indicate the level of protection of the high voltage system. Most vehicle systems are equipped with a single high voltage system, such that a single monitor is used to assess the resistance of the entire system. Vehicles are evolving to operate using fuel cell systems, such that there is a need to monitor more than one high voltage system within the vehicle systems.

### SUMMARY

In some aspects, an isolation resistance monitoring system for a high voltage direct current (DC) system includes a plurality of high voltage systems including a first high voltage link and a second high voltage link, a plurality of isolation monitors operably coupled with each of the first high voltage link and the second high voltage link to detect isolation resistance data, and a controller including data processing hardware configured to execute an isolation monitoring algorithm. The data processing hardware is also configured to execute an isolation function based on the isolation resistance. The isolation monitoring algorithm is configured to determine an isolation resistance level of each of the first high voltage link and the second high voltage link based on the isolation resistance data.

In some examples, the isolation resistance monitoring system may include a first switched resistor and a second switched resistor each coupled to the plurality of isolation monitors and the controller. Optionally, the plurality of high voltage systems may include a first high voltage system and a second high voltage system. The first high voltage system may be a fuel cell system, and the second high voltage system may be a rechargeable energy storage system. In some instances, the isolation function may include at least one of a low isolation alert and a termination function.

In some configurations, the plurality of isolation monitors may be configured to separately measure the isolation resistance data at each of the first high voltage link and the second high voltage link during a single cycle of each of the plurality of high voltage systems. Optionally, the plurality of isolation monitors may be configured to simultaneously monitor each of the first high voltage link and the second high voltage link for a low isolation indication. The isolation resistance data may include the low isolation indication.

In other aspects, an isolation resistance monitoring system for a high voltage direct current (DC) system includes a converter, a plurality of high voltage links, each of the plurality of high voltage links being connected via the converter, and a plurality of isolation monitors operably coupled with each of the plurality of high voltage links to measure isolation resistance data, the isolation resistance data including a resistance level of each high voltage link. The isolation resistance monitoring system also includes a controller including data processing hardware configured to execute an isolation monitoring algorithm. The data processing hardware is also configured to execute an isolation function based on the isolation resistance. The isolation monitoring algorithm is configured to separately determine an isolation resistance level of each high voltage link based on the isolation resistance data.

In some examples, the plurality of high voltage links may include a first high voltage link, a second high voltage link, and a third high voltage link. A first high voltage system and a second high voltage system may be associated with respective ones of the plurality of high voltage links. The first high voltage system may be a fuel cell system, and the second high voltage system may be a rechargeable energy storage system. Optionally, the isolation function may include at least one of a low isolation alert and a termination function. In some instances, the plurality of isolation monitors may be configured to separately measure the isolation resistance data at each high voltage link during a single cycle of the isolation resistance monitoring system. In some configurations, the converter may be a non-isolated DC-DC converter. Optionally, the isolation resistance data may include a low isolation indication.

In further aspects, a computer-implemented method, when executed by data processing hardware, causes the data processing hardware to perform operations. The operations include monitoring, via a plurality of isolation monitors, a resistance level of each of a first high voltage link and a second high voltage link of a high voltage direct current electric power system, determining, based on the monitored resistance level, an isolation resistance level of each of the first high voltage link and the second high voltage link via an isolation monitoring algorithm, and detecting, at one or more of the first high voltage link and the second high voltage link, a low isolation via the plurality of isolation monitors. The operations also include generating, via the isolation monitoring algorithm, a low isolation indication based on the detected low isolation and executing, at a controller, a low isolation function based on the low isolation indication.

In some examples, executing the low isolation function may include generating a low isolation alert. Optionally, executing the low isolation function may include executing a termination function of the high voltage direct current electric power system. In some instances, determining the isolation resistance levels may include calculating, via the isolation monitoring algorithm, the isolation resistance levels using the resistance level at each of the first high voltage link and the second high voltage link. In further examples, the operations may include gathering, via the isolation monitoring algorithm, isolation resistance data from each of the first high voltage link and the second high voltage link. The operations may also include scaling the isolation monitoring algorithm in response to one or more additional high voltage links.

A vehicle may include the isolation monitoring system and execute the method described herein.

### BRIEF DESCRIPTION OF THE DRAWINGS

The drawings described herein are for illustrative purposes only of selected configurations and are not intended to limit the scope of the present disclosure.

FIG. 1 is a schematic diagram of an isolation resistance monitoring system according to the present disclosure shown in conjunction with a vehicle;

FIG. 2 is an exemplary block diagram of an isolation resistance monitoring system according to the present disclosure;

FIG. 3 is a schematic diagram of a high voltage system of an isolation resistance monitoring system according to the present disclosure;

FIG. 4 is a schematic diagram of another high voltage system of an isolation resistance monitoring system according to the present disclosure; and

FIG. 5 is an exemplary flow diagram of an isolation resistance monitoring system according to the present disclosure.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to,” “attached to,” or “coupled to” another element or layer, it may be directly on, engaged, connected, attached, or coupled to the other element or layer, or intervening elements or layers may be present. In contrast, when an element is referred to as being “directly on,” “directly engaged to,” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms “first,” “second,” “third,” etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first,” “second,” and other numerical terms do not imply a sequence or order unless clearly indicated by the context. Thus, a first element, component, region, layer or section discussed below could be termed a second element, component, region, layer or section without departing from the teachings of the example configurations.

In this application, including the definitions below, the term “module” may be replaced with the term “circuit.” The term “module” may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term “code,” as used above, may include software, firmware, and/or microcode, and may refer to programs, routines, functions, classes, and/or objects. The term “shared processor” encompasses a single processor that executes some or all code from multiple modules. The term “group processor” encompasses a processor that, in combination with additional processors, executes some or all code from one or more modules. The term “shared memory” encompasses a single memory that stores some or all code from multiple modules. The term “group memory” encompasses a memory that, in combination with additional memories, stores some or all code from one or more modules. The term “memory” may be a subset of the term “computer-readable medium.” The term “computer-readable medium” does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICS (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

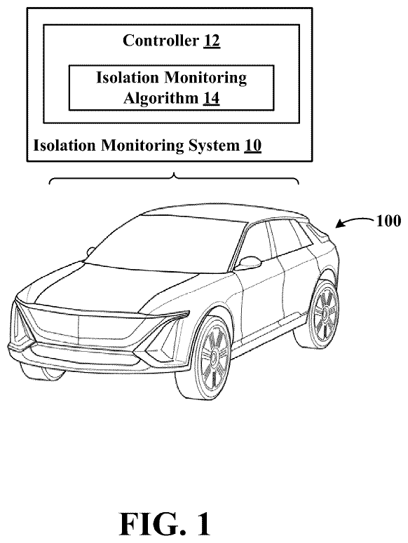

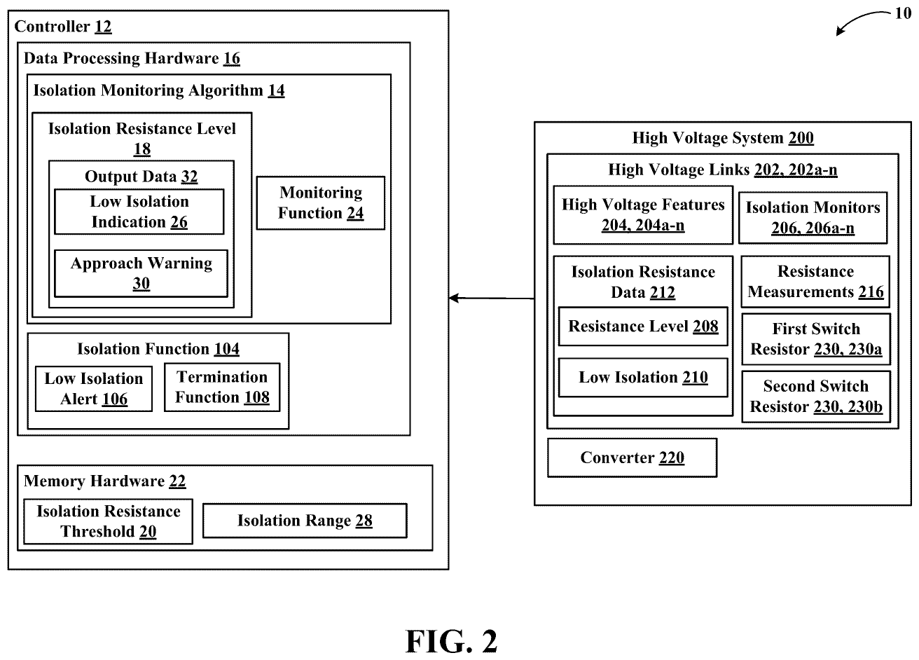

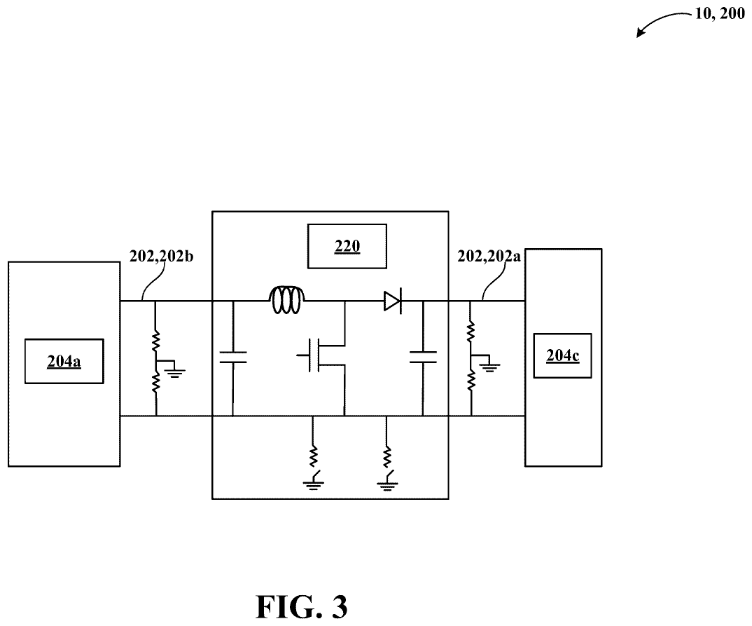

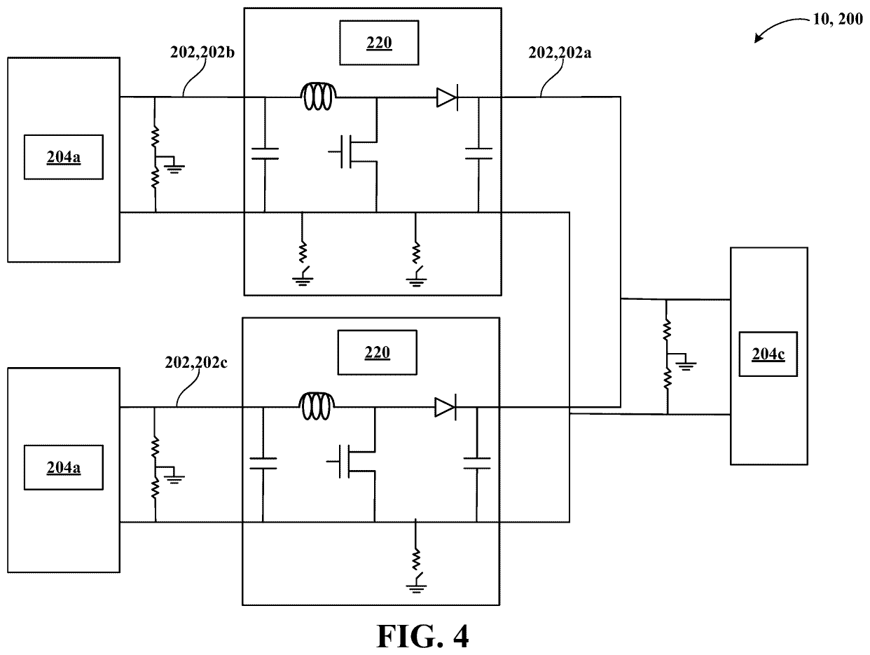

Referring to FIGS. 1-5, an isolation resistance monitoring system 10 configured for a high voltage (HV) direct current (DC) electric power system 100 or HVDC system 100 is provided. In one non-limiting example, the HVDC system 100 may be a vehicle. The isolation resistance monitoring system 10 also includes a controller 12. The controller 12 being configured with an isolation monitoring algorithm 14 of the isolation resistance monitoring system 10. The isolation resistance monitoring system 10 also includes at least one high voltage system 200 of the HVDC system 100. The high voltage system 200 includes a plurality of high voltage links 202, 202a-n that are connected via a converter 220. In some examples, the converter 220 may be a non-isolated DC-DC converter 220. The high voltage links 202, 202a-n interconnect high voltage features 204, 204a-n of the high voltage system 200. For example, the high voltage links 202, 202a-n may be configured to interconnect one or more fuel cell stacks 204, 204a with a battery 204, 204c of the high voltage system 200. The high voltage system 200 also include a plurality of isolation monitors 206, 206a-n configured to monitor a resistance level 208 of each respective high voltage link 202, 202a-n. At least two switched resistors 230 may be connected or otherwise coupled with the isolation monitors 206, 206a-n. For example a first switched resistor 230, 230a and a second switched resistor 230, 230b may each be coupled to the plurality of isolation monitors 206, 206a-n and the controller 12. The isolation resistance monitoring system 10 advantageously monitors the high voltage links 202, 202a-n to detect potential low isolation 210 at one or more of the high voltage links 202, 202a-n and execute functions of the isolation resistance monitoring system 10 to maintain safety standards of the HVDC system 100.

Referring to FIGS. 1-4, the controller 12 includes data processing hardware 16 configured to execute the isolation monitoring algorithm 14. In some examples, the controller 12 may be configured as part of the HVDC system 100 and may include the data processing hardware 16 to execute the isolation monitoring algorithm 14. The isolation monitoring algorithm 14 is configured to determine an isolation resistance level 18 of each of the high voltage links 202, 202a-n. For example, the isolation monitoring algorithm 14 may receive isolation resistance data 212 from the high voltage links 202, 202a-n and may utilize the isolation resistance data 212, which includes the resistance levels 208, to determine the isolation resistance level 18 for each high voltage link 202, 202a-n. The isolation resistance monitoring system 10 is configured to simultaneously monitor multiple high voltage links 202, 202a-n, such that the isolation monitoring algorithm 14 may be scaled depending on the number of high voltage links 202, 202a-n used with the HVDC system 100.

The isolation monitoring algorithm 14 may receive the isolation resistance data 212, including the resistance levels 208, from each high voltage link 202, 202a-n and utilize the determined isolation resistance level 18 to execute an isolation function 104. As described herein, the controller 12 is configured to execute the isolation function 104 based on the isolation resistance data 212 and isolation resistance level 18 from the controller 12. The isolation function 104 includes at least one of a low isolation alert 106 and a termination function 108.

Low isolation 210 of the high voltage links 202, 202a-n may correspond to a predetermined resistance level 208 being below an isolation resistance threshold 20, which may be stored in memory hardware 22 of the controller 12 for reference by the isolation monitoring algorithm 14. The isolation resistance threshold 20 may be defined as corresponding to a degree of isolation between a first high voltage link 202, 202a and one or more second high voltage links 202, 202b-n. The isolation resistance threshold 20 is calibrated as part of the isolation resistance monitoring system 10 and used by the isolation monitoring algorithm 14 to determine the isolation resistance level 18 of the respective high voltage links 202, 202a-n

Each of the high voltage links 202, 202a-n includes an isolation monitor 206, 206a-n to monitor and detect the isolation resistance data 212, including the resistance level 208 of each high voltage link 202, 202a-n. The isolation monitors 206, 206a-n provide the isolation resistance monitoring system 10 with active monitoring of multiple, interconnected high voltage links 202, 202a-n. For example, a first isolation monitor 206a may monitor a first high voltage link 202a on a first side (e.g., a low-side of a boost converter) and a second isolation monitor 206b may monitor a second high voltage link 202b on an opposing, second side (e.g., a high-side of a boost converter) of the high voltage system 200. In some examples, the second high voltage link 202b may be at the fuel cell stack 204a. In some instances, the HVDC system 100 may be configured with multiple fuel cell stacks 204a, such that there may be multiple high voltage links 202, 202a-n between the fuel cell stacks 204a and the battery 204c of the high voltage system 200. Thus, the isolation monitoring algorithm 14 can simultaneously monitor multiple high voltage links 202, 202a-n at each fuel cell stack 204a and the battery 204c, which may be interconnected via the non-isolated DC-DC converter 220, mentioned above. In some instances, the fuel cell stack 202a may be connected to the battery 204c via the non-isolated DC-DC converter 220 via the high voltage links 202, 202a-n.

With further reference to FIGS. 1-4, the non-isolated DC-DC converter 220 may include at least one third high voltage link 202, 202c interconnecting at least one of the fuel stacks 204a and the battery 204c. For example, the non-isolated DC-DC converter 220 may be coupled to at least one of the first high voltage link 202, 202a and the second high voltage link 202, 202b. Additionally, the third high voltage link 202, 202c may be coupled to at least one of the first high voltage link 202, 202c via the non-isolated DC-DC converter 220. The third high voltage link 202, 202c may also include an isolation monitor 206, 206c to monitor the resistance level 208 at the third high voltage link 202, 202c. It is contemplated that the high voltage system 200 may include greater than three high voltage links 202, 202a-n, such that each high voltage link 202, 202a-n is configured with a respective isolation monitor 206, 206a-n, as generally mentioned above, to capture the isolation resistance data 212 at each high voltage link 202, 202a-n.

The isolation monitors 206, 206a-n may be configured to capture the isolation resistance data 212 at each high voltage link 202, 202a-n during a single cycle of the isolation resistance monitoring system 10. For example, the isolation monitoring algorithm 14 utilizes the gathered isolation resistance data 212 to monitor a protection level (i.e., the isolation resistance level 18) at each high voltage link 202, 202a-n. In some instances, the isolation monitors 206, 206a-n may detect a low isolation 210, which is indicative of an issue with the resistance level 208, at one or more of the high voltage links 202, 202a-n. Since each high voltage link 202, 202a-n includes a respective isolation monitor 206, 206a-n, the isolation monitoring algorithm 14 is able to identify which high voltage link 202, 202a-n is experiencing the low isolation 210.

The isolation monitoring algorithm 14 is configured to receive the isolation resistance data 212 from each high voltage link 202, 202a-n and execute calculations to determine the isolation resistance level 18 at each high voltage link 202, 202a-n. The controller 12 may be configured to stagger resistance measurements 216 by executing monitoring functions 24 at each isolation monitor 206, 206a-n. For example, the monitoring functions 24 may provide feedback for rail-to-chassis voltages and equivalent isolation resistance at each of the high voltage links 202, 202a-n. The isolation monitors 206, 206a-n may monitor the isolation resistance data 212 based on the monitoring functions 24 executed by the controller 12. The controller 12, as described below, utilizes the isolation resistance data 212 to calculate the isolation resistance level 18 of each of the high voltage links 202, 202a-n.

In some instances, the isolation monitors 206, 206a-n may detect the low isolation 210, and the isolation monitoring algorithm 14 receives the low isolation 210 as part of the isolation resistance data 212. In other instances, the isolation monitoring algorithm 14 receives the raw isolation resistance data 212, including the resistance level 208, and determines, based on the monitored resistance level 208, the isolation resistance level 18 of each high voltage link 202, 202a-n. When determining the isolation resistance levels 18 of each high voltage link 202, 202a-n, the isolation monitoring algorithm 14 calculates the isolation resistance levels 18 using the resistance level 208 at each high voltage link 202, 202a-n.

If the isolation resistance level 18 is determined by the isolation monitoring algorithm 14 to be low at any one or more of the high voltage links 202, 202a-n, the isolation monitoring algorithm 14 may issue a low isolation indication 26. The isolation monitoring algorithm 14 may calculate the isolation resistance level 18 at each high voltage link 202, 202a-n and compare the calculated isolation resistance level 18 with the isolation resistance threshold 20 to determine whether to issue the low isolation indication 26. For example, the first isolation monitor 206a may detect low isolation 210 at the first high voltage link 202a and communicate the low isolation 210 with the isolation monitoring algorithm 14 as part of the isolation resistance data 212 associated with the first high voltage link 202a. The isolation monitoring algorithm 14 may then utilize the isolation resistance data 212 received from the first isolation monitor 206a to determine the isolation resistance level 18 at the first high voltage link 202a. As part of that determination, the isolation monitoring algorithm 14 compares the isolation resistance level 18 with the isolation resistance threshold 20 to determine whether to issue the low isolation indication 26 for the first high voltage link 202a. Thus, the isolation monitoring algorithm 14 advantageously identifies one or more high voltage link 202, 202a-n of the high voltage system 200 at which there may be low isolation 210. In some examples, the isolation monitoring algorithm 14 may determine that a coolant conductivity of the fuel cell stack 204a may be high based on the resistance level 208.

In some instances, the isolation resistance level 18 may be approaching the isolation resistance threshold 20, but may still be within an isolation range 28 stored on the memory hardware 22. The isolation range 28 may correspond to a range of isolation of each high voltage link 202, 202a-n where the resistance level 208 is below the calibrated isolation resistance threshold 20. If the isolation resistance level 18 is approaching the isolation resistance threshold 20, the isolation monitoring algorithm 14 may send an approach warning 30 to the controller 12. The controller 12 is configured to utilize the isolation resistance level 18 and any corresponding notifications (i.e., the low isolation indication 26 and the approach warning 30) as output data 32. The controller 12 may process the output data 32 to execute the isolation function 104, mentioned above.

The isolation function 104 is configured as a response executed by the controller 12 in response to the isolation resistance data 212 processed by the isolation monitoring algorithm 14. As generally mentioned above, the isolation function 104 includes the low isolation alert 106 and the termination function 108. The controller 12 is configured to determine which isolation function 104 to execute based on the output data 32 received from the isolation monitoring algorithm 14. In some instances, the controller 12 may execute the low isolation alert 106 in response to the isolation resistance level 18 and the approach warning 30. For example, the low isolation alert 106 may be provided to an occupant and/or operator of the HVDC system 100 via an indicia, notification, or other safety icon (e.g., a safety light) along a dashboard or infotainment region of the HVDC system 100. In other examples, the controller 12 may execute the low isolation alert 106 in response to the isolation resistance level 18 and the low isolation indication 26, such that the execution of the isolation function 104 may depend on the configuration of the controller 12.

The controller 12 may execute the termination function 108 in response to the isolation resistance level 18 and the low isolation indication 26. The termination function 108 may be configured to shut down operation of the high voltage system 200. It is contemplated that the isolation resistance monitoring system 10 may implement a tiered approach to executing the isolation function 104 of the controller 12. For example, the occupant and/or operator of the HVDC system 100 would receive the low isolation alert 106 prior to execution of the termination function 108. In some instances, the controller 12 may be configured to execute the low isolation alert 106 a predetermined number of times prior to executing the termination function 108. The termination function 108 of the controller 12 is designed to operate in combination with other operational functions of the HVDC system 100, such that the high voltage system 200 is terminated gradually to prevent a sudden termination of operation of the HVDC system 100.

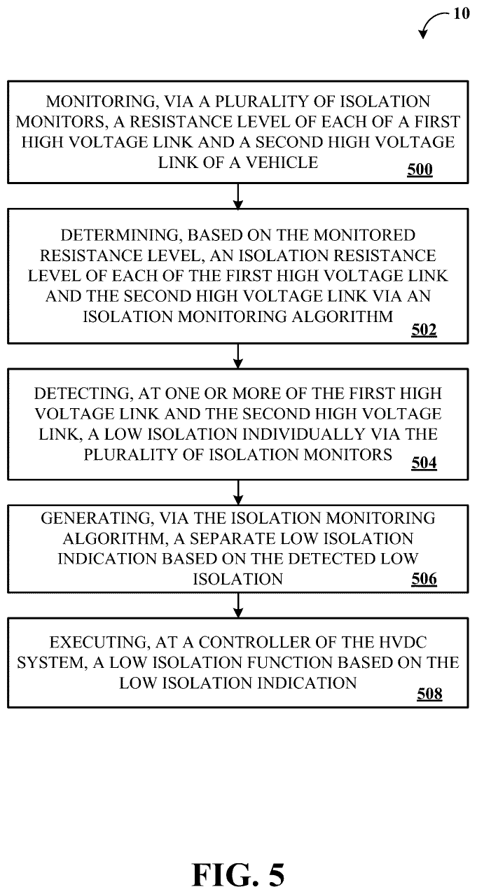

Referring to FIG. 5, an exemplary flow diagram for an isolation resistance monitoring system 10 is illustrated. At 500, the isolation resistance monitoring system 10 monitors, via the plurality of isolation monitors 206, 206a-n, a resistance level 208 of each of a first high voltage link 202, 202a and a second high voltage link 202, 202b and determines, at 502, based on the monitored resistance level 208, an isolation resistance level 18 of each of the first high voltage link 202, 202a and the second high voltage link 202, 202b via the isolation monitoring algorithm 14. The isolation resistance monitoring system 10 detects, at 504, at one or more of the first high voltage link 202, 202a and the second high voltage link 202, 202b, a low isolation 210 via the plurality of isolation monitors 206, 206a-n. At 506, the isolation resistance monitoring system 10 generates, via the isolation monitoring algorithm 14, a low isolation indication 26 based on the detected low isolation 210 and executes, at 508, at the controller 12 of the HVDC system 100, a low isolation function 104 based on the low isolation indication 26.

Referring again to FIGS. 1-5, the isolation resistance monitoring system 10 is configured to advantageously monitor each high voltage link 202, 202a-n of the high voltage system 200 via individual isolation monitors 206, 206a-n. The isolation monitors 206, 206a-n are configured at the various high voltage features 204, 204a-n of the high voltage system 200, such that each of a fuel cell stack(s) 204a, a battery 204c, and/or non-isolated DC-DC converter 220 may be configured with a respective isolation monitor 206, 206a-n. The individualized isolation monitors 206, 206a-n provide the isolation monitoring algorithm 14 with separate isolation resistance data 212, which is utilized to evaluate each of the high voltage links 202, 202a-n. Thus, the isolation resistance monitoring system 10 may advantageously identify a respective part or feature of the high voltage system 200, which may be experiencing low isolation 210.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. An isolation resistance monitoring system for a high voltage direct current (DC) system, the isolation resistance monitoring system comprising:
a plurality of high voltage systems including a first high voltage link and a second high voltage link;
a plurality of isolation monitors operably coupled with each of the first high voltage link and the second high voltage link to detect isolation resistance data; and
a controller including data processing hardware configured to execute an isolation monitoring algorithm and configured to execute an isolation function based on the isolation resistance, the isolation monitoring algorithm configured to determine an isolation resistance level of each of the first high voltage link and the second high voltage link based on the isolation resistance data.

2. The isolation resistance monitoring system of claim 1, further including a first switched resistor and a second switched resistor each coupled to the plurality of isolation monitors and the controller.

3. The isolation resistance monitoring system of claim 1, wherein the plurality of high voltage systems includes a first high voltage system and a second high voltage system, the first high voltage system being a fuel cell system and the second high voltage system being a rechargeable energy storage system.

4. The isolation resistance monitoring system of claim 1, wherein the isolation function includes at least one of a low isolation alert and a termination function.

5. The isolation resistance monitoring system of claim 1, wherein the plurality of isolation monitors are configured to separately measure the isolation resistance data at each of the first high voltage link and the second high voltage link during a single cycle of each of the plurality of high voltage systems.

6. The isolation resistance monitoring system of claim 1, wherein the plurality of isolation monitors is configured to simultaneously monitor each of the first high voltage link and the second high voltage link for a low isolation indication.

7. The isolation resistance monitoring system of claim 6, wherein the isolation resistance data includes the low isolation indication.

8. An isolation resistance monitoring system for a high voltage direct current (DC) system, the isolation resistance monitoring system comprising:
a converter;
a plurality of high voltage links, each of the plurality of high voltage links being connected via the converter;
a plurality of isolation monitors operably coupled with each of the plurality of high voltage links to measure isolation resistance data, the isolation resistance data including a resistance level of each high voltage link; and
a controller including data processing hardware configured to execute an isolation monitoring algorithm and configured to execute an isolation function based on the isolation resistance, the isolation monitoring algorithm configured to separately determine an isolation resistance level of each high voltage link based on the isolation resistance data.

9. The isolation resistance monitoring system of claim 8, wherein the plurality of high voltage links includes a first high voltage link, a second high voltage link, and a third high voltage link.

10. The isolation resistance monitoring system of claim 8, further comprising a first high voltage system and a second high voltage system associated with respective ones of the plurality of high voltage links, the first high voltage system being a fuel cell system and the second high voltage system being a rechargeable energy storage system.

11. The isolation resistance monitoring system of claim 8, wherein the isolation function includes at least one of a low isolation alert and a termination function.

12. The isolation resistance monitoring system of claim 8, wherein the plurality of isolation monitors is configured to separately measure the isolation resistance data at each high voltage link during a single cycle of the isolation resistance monitoring system.

13. The isolation resistance monitoring system of claim 8, wherein the converter is a non-isolated DC-DC converter.

14. A vehicle including the isolation resistance monitoring system of claim 8.

15. A computer-implemented method when executed by data processing hardware causes the data processing hardware to perform operations comprising:
monitoring, via a plurality of isolation monitors, a resistance level of each of a first high voltage link and a second high voltage link of a high voltage direct current electric power system;
determining, based on the monitored resistance level, an isolation resistance level of each of the first high voltage link and the second high voltage link via an isolation monitoring algorithm;
detecting, at one or more of the first high voltage link and the second high voltage link, a low isolation via the plurality of isolation monitors;
generating, via the isolation monitoring algorithm, a low isolation indication based on the detected low isolation; and
executing, at a controller, a low isolation function based on the low isolation indication.

16. The method of claim 15, wherein executing the low isolation function includes generating a low isolation alert.

17. The method of claim 15, wherein executing the low isolation function includes executing a termination function of the high voltage direct current electric power system.

18. The method of claim 15, wherein determining the isolation resistance levels includes calculating, via the isolation monitoring algorithm, the isolation resistance levels using the resistance level at each of the first high voltage link and the second high voltage link.

19. The method of claim 15, further including gathering, via the isolation monitoring algorithm, isolation resistance data from each of the first high voltage link and the second high voltage link.

20. The method of claim 15, further including scaling the isolation monitoring algorithm in response to one or more additional high voltage links.
